(19) United States
(12) Patent Application Publication
(10) Pub. No.: US 2025/0212682 A1
(43) Pub. Date: Jun. 26, 2025

(54) FILM, PREPARATION METHOD THEREOF AND PHOTOELECTRIC DEVICE

(71) Applicant: TCL Technology Group Corporation, Huizhou (CN)

(72) Inventors: Mi YUAN, Huizhou (CN); Zizhe LU, Huizhou (CN)

(73) Assignee: TCL Technology Group Corporation, Huizhou (CN)

(21) Appl. No.: 19/000,299

(22) Filed: Dec. 23, 2024

(30) Foreign Application Priority Data
Dec. 26, 2023 (CN) 202311811543.7

(51) Int. Cl. H10K 85/60; H10K 50/17

(52) U.S. Cl. CPC H10K 85/657; H10K 50/171

(57) ABSTRACT

The present disclosure film, preparation method thereof and photoelectric device. A film, a material of the film includes material and modifier. The modifier includes benzothiadiazole compound. The film provided by the present disclosure is beneficial to improving the electron transfer rate.

This application claims priority to Chinese Application No. 202311811543.7, entitled “FILM, PREPARATION METHOD THEREOF, PHOTOELECTRIC DEVICE AND DISPLAY DEVICE”, filed on Dec. 26, 2023. The entire disclosures of the above application are incorporated herein by reference.

### TECHNICAL FIELD

The present disclosure relates to a field of display technologies, and more particularly, to film, preparation method thereof and photoelectric device.

### BACKGROUND

The charge connection layer generally includes an electron generation layer and a hole generation layer, and n-type semiconductor material is usually selected as the material of the electron generation layer. In the related art, the charge transfer rate of the electron generation layer is poor, which needs to be further improved.

### Technical Solution

In view of this, the present disclosure provides a film, a preparation method thereof and a photoelectric device.

The present disclosure provides a film. A material of the film includes n-type semiconductor material and modifier, and the modifier includes benzothiadiazole compound.

The present disclosure provides a preparation method of a film, including: forming a film, wherein a material of the film includes n-type semiconductor material and modifier, and the modifier includes benzothiadiazole compound.

The present disclosure provides a photoelectric device, including: an anode; a cathode; several photoelectric units, located between the anode and the cathode; and a connecting layer, located between every two adjacent photoelectric units, and each connecting layer includes an electron generating layer and a hole generating layer arranged in sequence along the direction away from the anode. Wherein the electron generating layer includes a film, and a material of the film includes n-type semiconductor material and modifier, and the modifier includes benzothiadiazole compound.

The film provided by the present disclosure is beneficial to improving the electron transfer rate.

### BRIEF DESCRIPTION OF DRAWINGS

In order to more clearly explain the technical solutions in the embodiments of the present disclosure, the following will briefly introduce the drawings required in the description of the embodiments. Obviously, the drawings in the following description are only some embodiments of the present disclosure. For those skilled in the art, without paying any creative work, other drawings can be obtained based on these drawings.

FIG. 1 is a schematic diagram of the structure of a film according to an embodiment of the present disclosure.

FIG. 2 is a schematic diagram of the structure of a film according to another embodiment of the present disclosure.

FIG. 3 is a flowchart of a method for preparing a film according to an embodiment of the present disclosure.

FIG. 4 is a flowchart of a method for preparing a film according to another embodiment of the present disclosure.

FIG. 5 is a flowchart of a method for preparing a film according to another embodiment of the present disclosure.

FIG. 6 is a flowchart of a method for preparing a film according to another embodiment of the present disclosure.

FIG. 7 is a flowchart of a method for preparing a film according to another embodiment of the present disclosure.

FIG. 8 is a flowchart of a method for preparing a film according to another embodiment of the present disclosure.

FIG. 9 is a schematic diagram of the structure of a photoelectric device according to an embodiment of the present disclosure.

FIG. 10 is a schematic diagram of the structure of a photoelectric device according to another embodiment of the present disclosure.

FIG. 11 is a schematic diagram of the structure of an upright photoelectric device according to an embodiment of the present disclosure.

FIG. 12 is a schematic diagram of the structure of an inverted photoelectric device according to an embodiment of the present disclosure.

### DETAILED DESCRIPTION

Technical solutions in embodiments of the present disclosure will be clearly and completely described below in conjunction with drawings in the embodiments of the present disclosure. Obviously, the described embodiments are only a part of embodiments of the present disclosure, rather than all the embodiments. Based on the embodiments in the present disclosure, all other embodiments obtained by those skilled in the art without creative work fall within the protection scope of the present disclosure.

Additionally, in the description of the present disclosure, the term “comprising/including” means “comprising/including but not limited to.” Various embodiments of the present disclosure may be presented in a form of range. It should be understood that the description in the form of range is merely for convenience and brevity, and should not be construed as a hard limitation on the scope of the disclosure. Accordingly, it should be considered that the recited range description has specifically disclosed all possible subranges, as well as a single numerical value within that range. For example, it should be considered that a description of a range from 1 to 6 has specifically disclosed subranges, such as from 1 to 3, from 1 to 4, from 1 to 5, from 2 to 4, from 2 to 6, from 3 to 6, etc., and a single number within the range, such as 1, 2, 3, 4, 5, and 6, regardless of the range. Whenever a range of values is indicated herein, it is meant to include any recited number (fraction or integer) within the indicated range.

In the present disclosure, the term “and/or” is used to describe the association of associated objects, and means that there may be three relationships, for example, “A and/or B” may refer to three cases: the first case refers to the presence of A alone; the second case refers to the presence of both A and B; the third case refers to the presence of B alone, where A and B may be singular or plural.

In the present disclosure, the term “at least one” refers to one or more, and “a plurality of/multiple” refers to two or more. The terms “at least one”, “at least one of the followings”, or the like, refer to any combination of the items listed, including any combination of the singular or the plural items. For example, “at least one of a, b, or c” or “at least one of a, b, and c” may refer to: a, b, c, a-b (i.e., a and b), a-c, b-c, or a-b-c, where a, b, and c may be single or plural.

In a laminated photoelectric device, a plurality of photoelectric devices are connected through an electron generation layer and a hole generation layer, and electrons generated by the electron generation layer and holes generated by the hole generation layer are injected into different photoelectric devices respectively. However, electrons generated by adjacent electron generation layers and holes generated by hole generation layers often recombine internally, which affects the recombination efficiency of holes and electrons in the luminescent layer, and further affects the photoelectric efficiency of photoelectric devices.

The present disclosure discloses a film, and a material of the film includes n-type semiconductor material and modifier. The modifier includes benzothiadiazole compound.

In the film provided by this present disclosure, the modifier includes the benzothiadiazole compound, and the benzothiadiazole compound have the characteristics of electron deficiency, so that they have strong electron affinity, coplanarity and good regulation of the energy gap of the compounds, and might induce the separated electrons to transfer and transport rapidly and accelerate the charge transfer electric field locally.

When the film is applied to electron generation layer 41, the internal recombination of electrons generated by the electron generation layer 41 and holes generated by the hole generation layer 42 might be reduced, thereby improving the photoelectric efficiency of the photoelectric device.

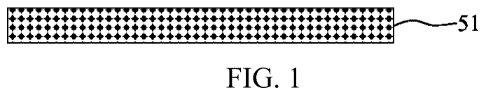

In some embodiments, referring to FIG. 1, the modifier includes a first modifier, and the first modifier includes the benzothiadiazole compound. The film includes a first sub-film 51, and a material of the first sub-film 51 includes the n-type semiconductor material and the first modifier.

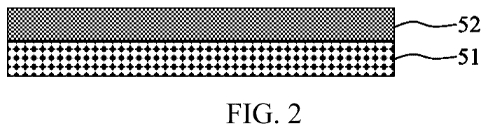

In some embodiments, referring to FIG. 2, the modifier includes a second modifier, and the second modifier includes the benzothiadiazole compound. The film includes a first sub-film 51 and a second sub-film 52 which are arranged in layers, wherein a material of the first sub-film 51 includes the n-type semiconductor material, and a material of the second sub-film 52 includes the second modifier.

In some embodiments, the modifier includes a first modifier and a second modifier, the first modifier and the second modifier are independently selected from the benzothiadiazole compound. The film includes a first sub-film 51 and a second sub-film 52 which are arranged in layers, wherein a material of the first sub-film 51 includes the n-type semiconductor material and the first modifier, and a material of the second sub-film 52 includes the second modifier.

In some embodiments, a structural formula of the benzothiadiazole compound is shown in the following formula:

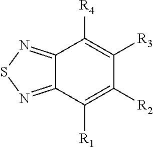

Wherein R₁, R₂, R₃ and R₄ are independently selected from hydrogen, deuterium, halogen, cyano, hydroxyl, carboxyl, aldehyde, nitro, substituted or unsubstituted C₁-C₂₀ alkyl group, substituted or unsubstituted C₂-C₂₀ alkenyl group, substituted or unsubstituted C₂-C₂₀ alkynyl group, substituted or unsubstituted C₁-C₂₀ alkoxy group and substituted or unsubstituted C₁-C₂₀ alkoxy group.

The halogen is selected from one or more of fluorine, chlorine, bromine and iodine.

The alkyl group is selected from one or more of methyl, ethyl, isopropyl and tert-butyl.

The alkenyl group is selected from one or more of vinyl group, propylene group and butene group.

The alkynyl group is selected from one or more of ethynyl group, propynyl group, pentynyl group and heptylynyl group.

The alkoxy group is selected from one or more of methoxy, ethoxy and propoxy.

The acyloxy is selected from one or more of formyloxy, acetoxy, propionyloxy, butyryloxy, octanoyloxy, palmitoyloxy and stearoyloxy.

The alkoxycarbonyl group is selected from one or more of methoxycarbonyl group, ethoxycarbonyl group, propoxycarbonyl group, butoxycarbonyl group, octyloxycarbonyl group, palmyloxycarbonyl group and stearyloxycarbonyl group.

The heteroatom in the heterocyclic group is selected from one or more of O, P, N and S.

The heterocyclic group is selected from one or more of thiazolyl, thienyl, furyl, pyrrolyl, pyridyl, pyrimidinyl, imidazolyl, oxazolyl, pyrazinyl, indolyl, quinoline, pteridinyl and acridine.

The aryl group is selected from one or more of phenyl, p-tolyl, p-nitrophenyl, o-methoxyphenyl, m-methoxyphenyl, p-methoxyphenyl and p-nitromethoxyphenyl.

The substituted group is independently selected from one or more of —NH, —F, —Cl, —Br, —I, —OH, —COOH, —NO, —SOH, —CHO, —SH and —CN.

In some embodiments, the benzothiadiazole compound is selected from 2,1,3-benzothiadiazole, 2,1,3-benzothiadiazol-4-yl isoxyanate, 4-aminobenzo-2,1,3-thiadiazole, 2,1,3-benzothiadiazole-5-carbaldehyde, 2-mercapto-5-methyl-1,3,4-thiadiazole, 4-nitro-2,1,3-benzothiadiazole, 1,2,3-benzothiadiazole-5-carbonyl chloride, 4,7-dibromo-2,1,3-benzothiadiazole, 5-methyl-2-mercaptobenzothiazole and cyclohexylamine salt of 2-mercaptobenzothioazole.

It should be noted that a material of the first modifier and the second modifier are the same or different.

In some embodiments, the n-type semiconductor material is selected from one or more of first doped metal oxide particle, first undoped metal oxide particle, IIB-VIA semiconductor material, IIIA-VA semiconductor material and IB-IIIA-VIA semiconductor material. A material of the first undoped metal oxide particle is selected from one or more of ZnO, TiO₂, SnO₂, ZrO₂ and Ta₂O₅. A metal oxide in the first doped metal oxide particle is selected from one or more of ZnO, TiO₂, SnO₂, ZrO₂, Ta₂O₅ and Al₂O₃. A doping element in the first doped metal oxide particle is selected from one or more of Al, Mg, Li, Mn, Y, La, Cu, Ni, Zr, Ce, In and Ga. The IIB-VIA semiconductor material is selected from one or more of ZnS, ZnSe and CdS. The IIIA-VA semiconductor material is selected from one or more of InP and GaP. The IB-IIIA-VIA family semiconductor material is selected from one or more of CuInS and CuGaS.

In some embodiments, an average particle size of the n-type semiconductor material ranges between 2 nm-6 nm, such as 2.5 nm, 3 nm, 3.5 nm, 4 nm, 4.5 nm, 5 nm, and 5.5 nm, etc.

In some embodiments, a mass ratio of the n-type semiconductor material to the first modifier is 30:(1-5), such as 30:2, 30:3, 30:4, etc. Within the range of the mass ratio, it is beneficial to the rapid electron transfer and transport induced by the first modifier.

In some embodiments, a thickness of the first sub-film 51 ranges between 10 nm-50 nm, such as 15 nm, 20 nm, 25 nm, 30 nm, 35 nm, 40 nm, 45 nm, etc. Within the range of the thickness, the transmission of electrons is smooth and the first sub-film 51 is uniform and flat.

In some embodiments, a thickness of the second sub-film 52 ranges between 1 nm-5 nm, such as 1.5 nm, 2 nm, 2.5 nm, 3 nm, 3.5 nm, 4 nm, 4.5 nm, etc. Within the range of the thickness, the second modifier will not affect the normal operation of the first sub-film 51, and might also promote the separation of electrons and holes.

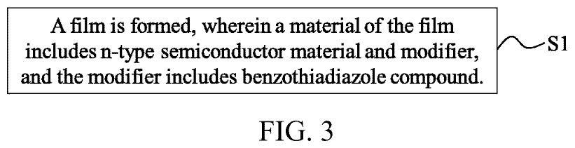

Referring to FIG. 3, the present disclosure proposes a preparation method of a film which includes step S1.

In step S1, a film is formed, wherein a material of the film includes n-type semiconductor material and modifier, and the modifier includes benzothiadiazole compound.

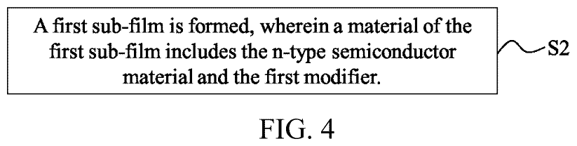

In some embodiments, the modifier includes a first modifier, and the first modifier includes the benzothiadiazole compound. Referring to FIG. 4, the film includes a first sub-film 51, the formation of the film which includes steps S2.

In step S2, a first sub-film 51 is formed, wherein a material of the first sub-film 51 includes the n-type semiconductor material and the first modifier.

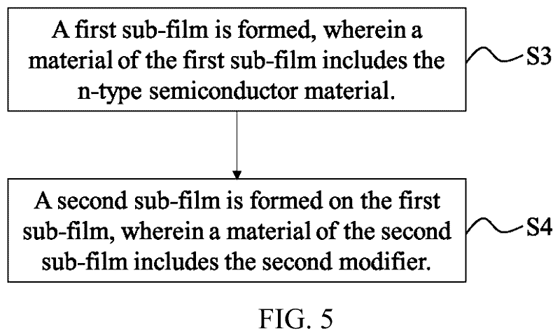

In other embodiments, referring to FIG. 5, the modifier includes a second modifier, and the second modifier includes the benzothiadiazole compound. The film includes a first sub-film 51 and a second sub-film 52, the formation of the film which includes step S3-S4.

In step S3, a first sub-film 51 is formed, wherein a material of the first sub-film 51 includes the n-type semiconductor material.

In step S4, a second sub-film 52 is formed on the first sub-film 51, wherein a material of the second sub-film 52 includes the second modifier.

It might be understood that when the film includes the first sub-film 51 and the second sub-film 52, the preparation method of the film might also prepare the second sub-film 52 first, and then prepare the first sub-film 51.

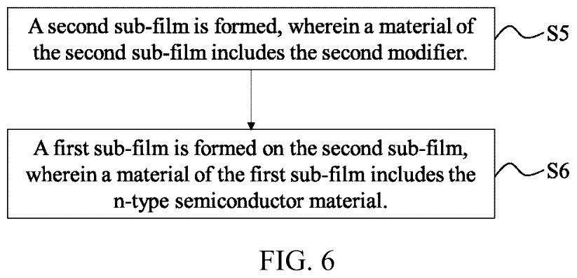

In other embodiments, the modifier includes a second modifier, and the second modifier includes the benzothiadiazole compound. Referring to FIG. 6, the film includes a first sub-film 51 and a second sub-film 52, the formation of the film which includes step S5-S6.

In step S5, a second sub-film 52 is formed, wherein a material of the second sub-film 52 includes the second modifier.

In step S6, a first sub-film 51 is formed on the second sub-film 52, wherein a material of the first sub-film 51 includes the n-type semiconductor material.

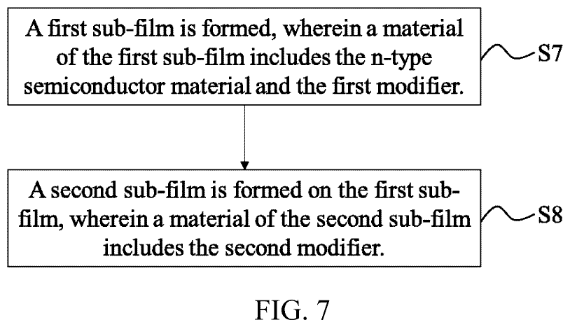

In other embodiments, the modifier includes a first modifier and a second modifier, and the first modifier and the second modifier are independently selected from the benzothiadiazole compound. Referring to FIG. 7, the film includes a first sub-film 51 and a second sub-film 52, the formation of the film which includes step S7-S8.

In step S7, a first sub-film 51 is formed, wherein a material of the first sub-film 51 includes the n-type semiconductor material and the first modifier.

In step S8, a second sub-film 52 is formed on the first sub-film 51, wherein a material of the second sub-film 52 includes the second modifier.

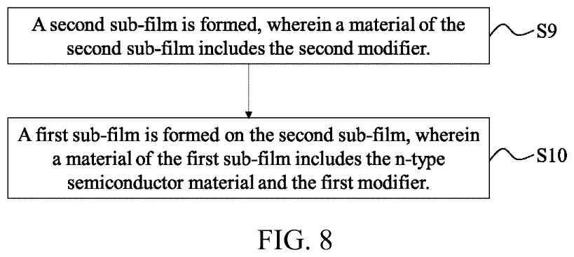

In other embodiments, the modifier includes a first modifier and a second modifier, and the first modifier and the second modifier are independently selected from the benzothiadiazole compound. Referring to FIG. 8, the film includes a first sub-film 51 and a second sub-film 52, the formation of the film which includes step S9-S10.

In step S9, a second sub-film 52 is formed, wherein a material of the second sub-film 52 includes the second modifier.

In step S10, a first sub-film 51 is formed on the second sub-film 52, wherein a material of the first sub-film 51 includes the n-type semiconductor material and the first modifier.

In some embodiments, when a material of the first sub-film 51 includes the n-type semiconductor material and the first modifier, a method of forming the first sub-film 51 includes: a first mixed liquid is provided, wherein the first mixed liquid includes the n-type semiconductor material and the first modifier; and the first mixed liquid is deposited to form the first sub-film 51.

In some embodiments, a mass concentration of the n-type semiconductor material in the first mixed liquid ranges between 10 mg/ml-50 mg/ml, such as 15 mg/mL, 20 mg/mL, 25 mg/mL, 30 mg/mL, 35 mg/mL, 40 mg/mL, 45 mg/mL, etc. Within the range of the mass concentration, the n-type semiconductor material is easy to disperse evenly and is not easy to agglomerate.

In some embodiments, a mass concentration of the first modifier in the first mixed solution ranges between 1 mg/ml-5 mg/ml, such as 2 mg/mL, 3 mg/mL, 4 mg/mL, etc.

In some embodiments, the first mixed liquid further includes a first solvent.

The first solvent is selected from one or more of chlorobenzene, diethylene glycol monobutyl ether, trimethoxybutanol, triethylene glycol monobutyl ether, diethylene glycol dimethyl ether, methanol, ethanol, propanol, butanol, ethylene glycol, isopropanol, glycerol, dimethyl sulfoxide, acetone, acetophenone, tetrahydrofuran, N,N-dimethylformamide, ethyl acetate, pyrrole, butyric acid and cresol.

In some embodiments, after the first mixed liquid is deposited, the method of forming the first sub-film 51 further includes: annealing.

A temperature of the annealing ranges between 80° C.-120° C., such as 90° C., 100° C., 110° C., etc. A time of the annealing ranges between 5 min-10 min, such as 6 min, 7 min, 8 min, 9 min, etc. Thus, under the annealing condition, the ligand activity on the surface of the first sub-film layer 51 might be ensured, the steric hindrance might be reduced, the electron transmission efficiency might be improved, and the first solvent might be effectively removed.

In some embodiments, a method of forming the second sub-film 52 includes: a second mixed liquid is provided, wherein the second mixed liquid includes the second modifier; and the second mixed liquid is deposited to form the second sub-film 52.

In some embodiments, a mass concentration of the second modifier in the second mixed solution ranges between 1 mg/ml-5 mg/ml, such as 2 mg/mL, 3 mg/mL, 4 mg/mL, etc.

In some embodiments, the second mixed liquid further includes a second solvent.

The second solvent is selected from one or more of chlorobenzene, diethylene glycol monobutyl ether, trimethoxybutanol, triethylene glycol monobutyl ether, diethylene glycol dimethyl ether, methanol, ethanol, propanol, butanol, ethylene glycol, isopropanol, glycerol, dimethyl sulfoxide, acetone, acetophenone, tetrahydrofuran, N,N-dimethylformamide, ethyl acetate, pyrrole, butyric acid and cresol.

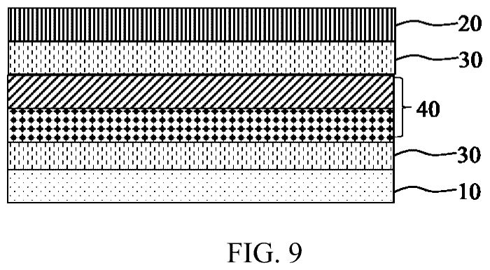

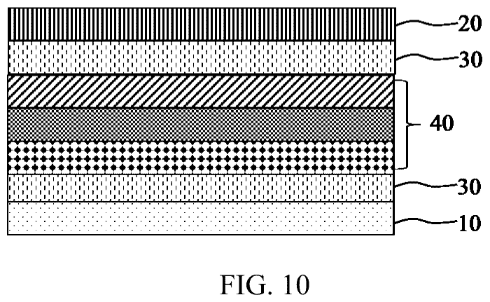

Referring to FIG. 9 and FIG. 10, the present disclosure discloses a photoelectric device, including:
an anode 10;
a cathode 20;
several photoelectric units 30, located between the anode 10 and the cathode 20; and
a connecting layer 40, located between every two adjacent photoelectric units 30, and each connecting layer 40 includes an electron generating layer 41 and a hole generating layer 42 arranged in sequence along the direction away from the anode 10.

The electron generating layer 41 includes the film which above-mentioned, or a film prepared by above-mentioned preparation method. When the film includes a first sub-film 51 and a second sub-film 52, the second sub-film 52 is located between the first sub-film 51 and the hole generating layer 42.

Each of the photoelectric unit 30 includes a hole functional layer, a luminescent layer and an electronic functional layer which are stacked.

The hole functional layer includes one or more of a hole injection layer and a hole transport layer.

The electronic functional layer includes one or more of an electronic injection layer and an electronic transport layer.

It might be understood that the photoelectric units 30 may include 2, 3, 4 or 5 or more photoelectric units 30. When the photoelectric units 30 include more than three, the first sub-films 51 in a plurality of connection layers may be doped with the first modifier, or any one of the first sub-films 51 may be doped with the first modifier, and accordingly, a plurality of second sub-films 52 or one second sub-film 52 may be included.

In some embodiments, the photoelectric units 30 include a first photoelectric unit 31 and a second photoelectric unit 32.

The first photoelectric unit 31 includes a first hole functional layer 311, a first luminescent layer 312, and a first electronic functional layer 313 which are sequentially stacked. Accordingly, the second photoelectric unit 32 includes a second hole functional layer 321, a second luminescent layer 322, and a second electronic functional layer 323 which are sequentially stacked.

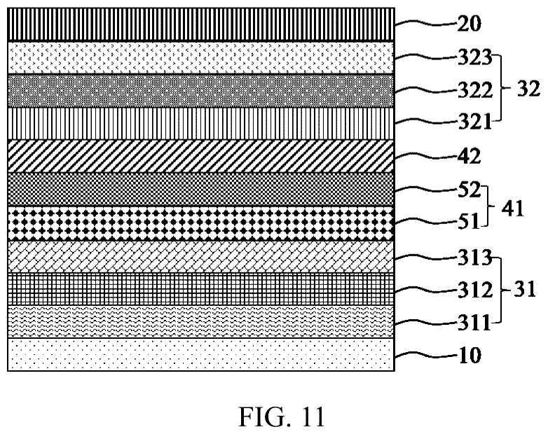

Referring to FIG. 11, in one embodiment, the photoelectric device is an upright photoelectric device, including the anode 10, the first hole functional layer 311, the first luminescent layer 312, the first electronic functional layer 313, the first sub-film 51, the second sub-film 52, the hole generating layer 42, the second hole functional layer 321, the second luminescent layer 322, the second electronic functional layer 323 and the cathode 20 which are sequentially stacked.

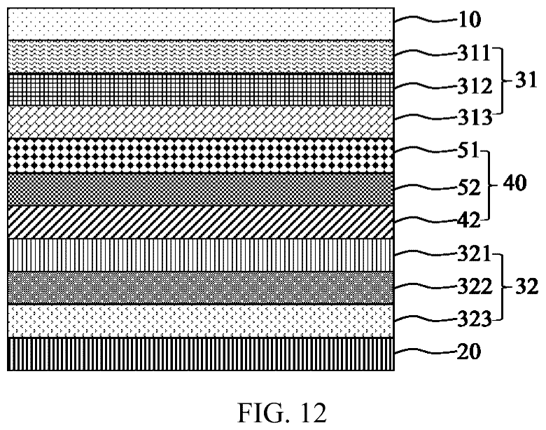

Referring to FIG. 12, in another embodiment, the photoelectric device is an inverted photoelectric device, including the cathode 20, the second electronic functional layer 323, the second luminescent layer 322, the second hole functional layer 321, the hole generating layer 42, the second sub-film 52, the first sub-film 51, the first electronic functional layer 313, the first luminescent layer 312, the first hole functional layer 311 and the anode 10 which are sequentially stacked.

A material of the anode 10 and the cathode 20 is each independently selected from one or more of metal, carbon material and metal oxide. The metal is selected from one or more of Al, Ag, Cu, Mo, Au, Ba, Ca, Yb and Mg. The carbon material is selected from one or more of graphite, carbon nanotubes, graphene and carbon fiber. The metal oxide is selected from one or more of metal oxide electrode or composite electrode with metal sandwiched between doped or undoped transparent metal oxide, and a material of the metal oxide electrode is selected from one or more of ITO, FTO, ATO, AZO, GZO, IZO, MZO, MoO₃ and AMO. The composite electrode is selected from one or more of AZO/Ag/AZO, AZO/Al/AZO, ITO/Ag/ITO, ITO/Al/ITO, ZnO/Ag/ZnO, ZnO/Al/ZnO, ZnS/Ag/ZnS, ZnS/Al/ZnS, TiO₂/Ag/TiO₂ and TiO₂/Al/TiO₂. Where “/” represents a laminated structure, for example, AZO/Ag/AZO represents a composite electrode including an AZO layer, an Ag layer and an AZO layer which are sequentially laminated.

In some embodiments, a material of luminescent layer in each photoelectric unit 30 is independently selected from one or more of organic luminescent material and quantum dot luminescent material.

A material of the organic luminescent material is selected from one or more of CBP:Ir(mppy)₃(4,4′-bis (N-carbazole)-1,1′-biphenyl: tris [2-(p-tolyl) pyridine iridium (III)]), TCTX:Ir(mmpy)(4,4′), 4″-tris (carbazole-9-yl) triphenylamine: tris [2-(p-tolyl) iridium pyridine]), diarylanthracene derivatives, stilbene aromatic derivatives, pyrene derivatives, fluorene derivatives, TBPe fluorescent materials, TTPX fluorescent materials, TBRb fluorescent materials, DBP fluorescent materials, delayed fluorescent materials, TTA materials, TADF (delayed thermal activation) materials, polymers containing B—N covalent bonds, HLCT (hybrid local charge transfer excited state) materials and Exciplex luminescent materials.

The quantum dot luminescent material might be selected from but not limited to one or more of single-structure quantum dot, core-shell quantum dot and perovskite-type semiconductor material.

A material of the single-structure quantum dot, a core material of the core-shell quantum dot and a shell material of the core-shell quantum dot might be respectively selected from but not limited to one or more of second II-VI compound, second IV-VI compound, second III-V compound and I-III-VI compound. A shell layer of the core-shell structure quantum dot comprises one or more layers. The second II-VI compound is selected from one or more of CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe. The second IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe and SnPbSTe. The second III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs and InAlPSb. The I-III-VI compound is selected from one or more of CuInS₂, CuInSe₂ and AgInS₂.

As an example, the core-shell quantum dot is selected from one or more of CdSe/CdSeS/CdS, InP/ZnSeS/ZnS, CdZnSe/ZnSe/ZnS, CdSe/ZnS, CdSe/ZnSe, ZnSe/ZnS, ZnSe/ZnS, ZnSe/ZnS, and ZnSe/ZnSe/ZnSe.

The perovskite semiconductor material is selected from one of doped or undoped inorganic perovskite semiconductor or organic-inorganic hybrid perovskite semiconductor. A general structural formula of the inorganic perovskite semiconductor is AMX₃, wherein A is Cs⁺, and X is divalent metal cation, which is selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺ and Eu²⁺, and X is a halogen anion selected from one or more of Cl⁻, Br⁻ and I⁻. The general structural formula of the organic-inorganic hybrid perovskite semiconductor is BMX₃, wherein B is an organic amine cation selected from CH₃(CH₂)ₙ₋₂NH₃⁺ or [NH₃(CH₂)ₙNH₃]²⁺, wherein n≥2, and M is a divalent metal cation selected from Pb²⁺, Sn²⁺, Cu²⁺, Ni²⁺, Cd²⁺ and Cr³⁺, and X is a halogen anion selected from one or more of Cl⁻, Br⁻ and I⁻.

In some embodiments, a material of the hole functional layer and the hole generating layer 42 is each independently selected from one or more of 4,4′-N,N′-dicarbazolyl-biphenyl, N,N′-diphenyl-N,N′-bis (1-naphthyl)-1,1′-biphenyl)-4,4′-diamine, N,N′-bis(3-methylphenyl)-N,N′-bis (phenyl)-spiro, N,N′-bis(4-(N,N′-diphenyl-amino) phenyl)-N,N′-diphenylbenzidine, 4,4′,4′-tris (N-carbazolyl)-triphenylamine, 4,4′,4′-tris (carbazole-9-yl) triphenylamine, trichloroisocyanuric acid, terbium-doped phosphate-based green luminescent material, 2,3,6,7,10,11-hexacyano-1,4,5,8,9,12-hexaazaphenanthrene, 4,4′,4′-tris (N-3-methylphenyl-N-phenylamino) triphenylamine, poly [(9,9′-dioctyl fluorene-2,7-diyl)-co-(4,4′-(N-(4-sec-butylphenyl) diphenylamine))], poly (4-butylphenyl-diphenylamine), poly [bis(4-phenyl) (4-butylphenyl) amine], polyaniline, polypyrrole, poly (p) phenylene vinylene, poly (phenylene vinylene), poly [2-methoxy-5-(2-ethylhexyloxy)-1,4-phenylene vinylene], poly [2-methoxy-5-(3′,7-dimethyl octyloxy)-1,4-phenylene vinylene], copper phthalocyanine, aromatic tertiary amine, 4,4′-bis (p-carbazolyl)-1,1′-biphenyl compound, N,N,N′,N′-tetraarylbenzidine, PEDOT, PEDOT:PSS and its derivatives, PEDOT:PSS derivatives doped with s-MoO₃, poly (N-vinylcarbazole) and its derivatives, polymethacrylate and its derivatives, poly (9,9-octylfluorene) and its derivatives, poly (spirofluorene) and its derivatives, N,N′-bis (naphthalene-1-yl)-N,N′-diphenylbenzidine, spiro NPB, nano-polycrystalline diamond, microcrystalline cellulose, tetracyanoquinone dimethylmethane, doped graphene and undoped graphene, second doped metal oxide particle, second undoped metal oxide particle, metal sulfide, metal selenide and metal nitride. A metal oxide in the second doped metal oxide particle and a metal oxide in the second undoped metal oxide particle is independently selected from one or more of MoO₃, WO₃, NiO, CrO₃, CuO, Cu₂O and V₂O₅. A doping element in the second doped metal oxide particle is selected from one or more of Mo, W, Ni, Cr, Cu and V. The metal sulfide is selected from one or more of CuS, MoS₃ and WS₃. The metal selenide is selected from one or more of MoSe₃ and WSe₃. The metal nitride is selected from p-type gallium nitride.

In some embodiments, a material of the electronic functional layer is selected from one or more of first doped metal oxide particle, first undoped metal oxide particle, IIB-VIA semiconductor material, IIIA-VA semiconductor material and IB-IIIA-VIA semiconductor material. A material of the first undoped metal oxide particle is selected from one or more of ZnO, TiO₂, SnO₂, ZrO₂ and Ta₂O₅. A metal oxide in the first doped metal oxide particle is selected from one or more of ZnO, TiO₂, SnO₂, ZrO₂, Ta₂O₅ and Al₂O₃. A doping element in the first doped metal oxide particle is selected from one or more of Al, Mg, Li, Mn, Y, La, Cu, Ni, Zr, Ce, In and Ga. The IIB-VIA semiconductor material is selected from one or more of ZnS, ZnSe and CdS. The IIIA-VA semiconductor material is selected from one or more of InP and GaP. The IB-IIIA-VIA family semiconductor material is selected from one or more of CuInS and CuGaS.

It might be understood that the photoelectric device provided by this present disclosure might be an upright photoelectric device or an inverted photoelectric device.

The present disclosure also discloses a display device, including the photoelectric device in any of the above embodiments.

The display device might be a mobile terminal such as a TV set, a mobile phone, a tablet computer, a computer monitor, or a device with a display screen such as a game device, an Augmented Reality (AR) device, a Virtual Reality (VR) device, a data storage device, an audio playback device, a video playback device, and a wearable device, wherein the wearable device might be a smart bracelet, smart glasses, and a smart watch.

This present disclosure will be explained in detail by specific examples. The following examples are only partial examples of this present disclosure, and are not limited to this present disclosure.

### Example 1

This example provides a film, which includes a first sub-film, a material of the first sub-film is the n-type semiconductor material and the first modifier, and a preparation method of the film includes steps S20-S21.

In step S20, 3 mg of a first modifier (2,1,3-benzothiadiazole), and 30 mg of n-type semiconductor material (magnesium-doped zinc oxide, ZnMgO) are provided and mixed, and then dissolved in ethanol to obtain a first mixed solution.

In step S21, the first mixed solution is deposited by spin coating, followed by heating at 80° C. for 10 min, and the first sub-film with a thickness of 40 nm is obtained.

### Example 2

This example is basically the same as Example 1, only the difference is that in this example, the first mixed solution does not contain 2,1,3-benzothiadiazole, and the material of the first sub-film does not contain 2,1,3-benzothiadiazole. After the first sub-film is obtained, it also includes: a second modifier (2,1,3-benzothiadiazole) is dissolved to obtain a second mixed solution with a concentration of 3 mg/mL, the second mixed solution is spin-coated on the first sub-film, and a second sub-film with a thickness of 3 nm is obtained.

### Example 3

This example is basically the same as Example 1, only the difference is that in this example, after the first sub-film is obtained, it also includes: a second modifier (2,1,3-benzothiadiazole) is dissolved to obtain a second mixed solution with a concentration of 3 mg/mL, the second mixed solution is spin-coated on the first sub-film, and a second sub-film with a thickness of 3 nm is obtained.

### Example 4

This example is basically the same as Example 1, only the difference is that in this example, 2,1,3-benzothiadiazole is replaced by 5-methyl-2-mercaptobenzothiazole.

### Example 5

This example is basically the same as Example 2, only the difference is that in this example, 2,1,3-benzothiadiazole is replaced by cyclohexylamine salt of 2-mercaptobenzothioazole.

### Example 6

This example is basically the same as Example 4, only the difference is that in this example, after the first sub-film is obtained, it also includes: a second modifier (cyclohexylamine salt of 2-mercaptobenzothioazole) is dissolved to obtain a second mixed solution with a concentration of 3 mg/mL, the second mixed solution is spin-coated on the first sub-film, and a second sub-film with a thickness of 3 nm is obtained.

### Example 7

This example is basically the same as Example 1, only the difference is that in this example, a mass of 2,1,3-benzothiadiazole is 5 mg.

### Example 8

This example is basically the same as Example 1, only the difference is that in this example, a mass of 2,1,3-benzothiadiazole is 1 mg.

### Example 9

This example is basically the same as Example 8, only the difference is that in this example, a mass of 2,1,3-benzothiadiazole is 8 mg.

### Comparative Example 1

This comparative example is basically the same as Example 1, only the difference is that in this comparative example, the first mixed solution does not contain 2,1,3-benzothiadiazole, and the material of the first sub-film does not contain 2,1,3-benzothiadiazole.

### Performance Test:

An electron mobility of films in Examples 1-9 and Comparative Example 1 were tested, and the results are shown in Table 1.

The testing method of electron mobility includes: controlling QE PRO and Keithley 2400 through LabView to build a QLED efficiency testing system, and testing the current density-voltage curve of single electronic transport thin film device (EOD) by this system, wherein the structure of EOD includes an anode (ITO), a luminescent layer (ZnCdSe/ZnS), an electronic transport layer and a cathode (Ag), and the electronic transport layer is the above-mentioned films. The space charge limited current (SCLC) region in the current density-voltage curve is obtained, and then the electron mobility is calculated according to the formula J=(9/8)εᵣε₀μₑV²/d³, where J represents the current density, and the unit is mA cm⁻²; εᵣ represents relative dielectric constant, ε₀ represents vacuum dielectric constant; μₑ represents electron mobility in cm²V⁻¹ s⁻¹; V represents the driving voltage, in V; D represents the film thickness in m.

TABLE 1

| | Electron mobility |
|---|---|
| | (×10⁻⁶ cm²V⁻¹s⁻¹) |
| Example 1 | 8.52 |
| Example 2 | 8.68 |
| Example 3 | 7.55 |
| Example 4 | 8.61 |
| Example 5 | 8.39 |
| Example 6 | 7.33 |
| Example 7 | 8.51 |
| Example 8 | 8.64 |
| Example 9 | 7.34 |
| Comparative Example 1 | 7.11 |

From examples 1-3 and comparative example 1, the electron mobility of the film might be improved by doping benzothiadiazole compound in the first sub-film and/or setting the second sub-film of benzothiadiazole compound on the first sub-film. Among them, in example 3, the scheme of doping the first sub-film and adding the second sub-film was adopted, which resulted in a large amount of the modifier, which had a certain effect on improving the electron mobility, but the effect was worse than that of adding the second sub-film or doping alone.

From examples 1, 4-6 and comparative example 1, both that first modifier and the second modifier provided by the present disclosure might effectively improve the electron mobility. Example 6 is similar to example 3, and the electron mobility of example 6 is slightly worse than that of examples 4-5 due to the much modifier.

From examples 1, 7-9 and comparative example 1, the amount of the first modifier will affect the electron mobility of the film. Within the preferred range provided by this present disclosure, the electron mobility of the films in examples 7-8 is higher, and there are more first modifiers in example 9, which is slightly worse than that in examples 7-8, but still better than that in comparative example 1.

### Photoelectric Device Example 1

This example provides a photoelectric device, and a preparation method of the photoelectric device includes steps S22-S32.

In step S22, an ITO glass is provided, and the surface of the ITO glass is wiped with a cotton swab dipped in a small amount of soapy water to remove impurities visible to the naked eye. Then, it is ultrasonically cleaned with deionized water, acetone, ethanol and isopropanol for 15 min, dried with nitrogen and irradiated with UV for 15 min to form ITO anode.

In step S23, a PEDOT:PSS with solute content of 1.5 wt % is spin-coated on the ITO anode, and then heated at 150° C. for 15 min to form a hole injection layer with a thickness of 30 nm.

In step S24, a TFB is dissolved in chlorobenzene at a concentration of 8 mg/mL, and then it is spin-coated on the hole injection layer at a rotation speed of 3000 rpm, followed by heating at 150° C. for 15 min to form a first hole transport layer with a thickness of 15 nm.

In step S25, a quantum dot solution of ZnCdSe/ZnS with a mass concentration of 10 mg/mL is prepared, and then spin-coated on the first hole transport layer at the rotating speed of 3000 rpm for 30 s, and then heated at 80° C. for 30 min to form a first luminescent layer with a thickness of 30 nm.

In step S26, a film is formed on the first luminescent layer according to the method of Example 1, and an electron generating layer is obtained.

In step S27, a PEDOT:PSS with solute content of 1.5 wt % is spin-coated on the electron generating layer to form a hole generating layer with a thickness of 10 nm.

In step S28, a TFB solution with a mass concentration of 8 mg/mL is spin-coated on the hole generating layer to form a second hole transport layer with a thickness of 15 nm.

In step S29, a quantum dot solution of ZnCdSe/ZnS is spin-coated on the second hole transport layer to form a second luminescent layer with a thickness of 30 nm.

In step S30, a solution of magnesium-doped zinc oxide (ZnMgO) is spin-coated on the second luminescent layer to form an electronic transport layer with a thickness of 40 nm.

In step S31, an Ag is evaporated by thermal evaporation on the electronic transport layer, vacuum degree is not higher than 3×10⁻⁴ Pa, the speed is 1 Å/s, the time is 1000 s, and a cathode with a thickness of 100 nm is obtained.

In step S32, a photoelectric device is obtained after packaging.

### Photoelectric Device Examples 2-9

Photoelectric device Examples 2-9 are basically the same as photoelectric device Example 1, and only the difference is that films are prepared by the methods of Examples 2-9, respectively, to obtain electron generating layers.

### Photoelectric Device Example 10

This Photoelectric device Examples is basically the same as photoelectric device Example 1, and the only difference is that the order of preparation of photoelectric devices in this device embodiment is the cathode, the electronic transport layer, the second luminescent layer, the second hole transport layer, the hole generation layer, the first sub-film, the first luminescent layer, the first hole transport layer, the hole injection layer and the anode.

### Photoelectric Device Example 11

This Photoelectric device Examples is basically the same as photoelectric device Example 2, and the only difference is that the order of preparation of photoelectric devices in this device embodiment is the cathode, the electronic transport layer, the second luminescent layer, the second hole transport layer, the hole generation layer, the second sub-film, the first sub-film, the first luminescent layer, the first hole transport layer, the hole injection layer and the anode.

### Photoelectric Device Example 12

This Photoelectric device Examples is basically the same as photoelectric device Example 3, and the only difference is that the order of preparation of photoelectric devices in this device embodiment is the cathode, the electronic transport layer, the second luminescent layer, the second hole transport layer, the hole generation layer, the second sub-film, the first sub-film, the first luminescent layer, the first hole transport layer, the hole injection layer and the anode.

### Photoelectric Device Comparative Example 1

This Photoelectric device Comparative Example is basically the same as photoelectric device Example 1, and only the difference is that the film is prepared by the method of Comparative Example 1, to obtain electron generating layer.

### Photoelectric Device Comparative Example 2

This Photoelectric device Comparative Example is basically the same as photoelectric device Example 10, and only the difference is that the first sub-film does not contain 2,1,3-benzothiadiazole.

### Performance Test:

The current efficiency (C.E.) of the photoelectric devices in Photoelectric device Examples 1-10 and Photoelectric device Comparative Examples 1-2 were tested respectively. The result obtained are shown in Table 2.

The current efficiency (C.E.) is measured and calculated by Keithley 2400 high-precision digital source meter, Ocean Optical USB 2000+ spectrometer and LS-160 luminometer.

TABLE 2

| | C.E. |
|---|---|
| | (cd/A) |
| Photoelectric device Example 1 | 7122 |
| Photoelectric device Example 2 | 7051 |
| Photoelectric device Example 3 | 7189 |
| Photoelectric device Example 4 | 7994 |
| Photoelectric device Example 5 | 7003 |
| Photoelectric device Example 6 | 7101 |
| Photoelectric device Example 7 | 8123 |
| Photoelectric device Example 8 | 7176 |
| Photoelectric device Example 9 | 7111 |
| Photoelectric device Example 10 | 7167 |
| Photoelectric device Comparative Example 1 | 7031 |
| Photoelectric device Comparative Example 2 | 1128 |

From the photoelectric device examples 1-3 and the photoelectric device comparative example 1, doping 2,1,3-benzothiadiazole into the first sub-film alone and/or adding a second sub-film of 2,1,3-benzothiadiazole between the first sub-film and the hole generating layer might avoid internal recombination of electrons generated by the first sub-film and holes generated by the hole generating layer, thus effectively improving the current efficiency of the photoelectric device. Among them, in photoelectric device example 3, the scheme of doping the first sub-film and adding the second sub-film was adopted, which leads to a large amount of the modifier in photoelectric device, which has a certain effect on improving the current efficiency of photoelectric device, but the effect is worse than that of adding the second sub-film or doping alone.

From the photoelectric device examples 1, 4-6 and photoelectric device comparative example 1, replacing the first modifier and the second modifier has no significant effect on the current efficiency of photoelectric devices. The photoelectric device example 6 is similar to the photoelectric device embodiment 3, and the improvement effect on the current efficiency of the photoelectric device is not as good as that of the photoelectric device examples 4-5 due to much modifier.

From photoelectric device examples 1, 7-9 and photoelectric device comparative example 2, the amount of the first modifier has certain influence on the current efficiency of photoelectric devices. Compared with photoelectric device examples 7-8, there are too many first modifier in photoelectric device example 9, which has better influence on the electron transmission performance than photoelectric device comparative example 1, but worse than the current efficiency of photoelectric device examples 7-8.

From photoelectric device examples 10-12 and photoelectric device comparative example 2, in the inverted photoelectric device, the current efficiency of the inverted photoelectric device might be effectively improved by doping modifier into the first sub-film alone and/or adding a second sub-film of modifier between the first sub-film and the hole generating layer. Similar to the inverted photoelectric device, the influence on upright photoelectric device when doping the modifier into the first sub-film and adding the second sub-film, the influence on the upright photoelectric device is slightly worse than that of doping the modifier into the first sub-film or adding the second sub-film alone.

Film, preparation method thereof and photoelectric device are described in detail above. The principles and embodiments of the present disclosure have been described with reference to specific embodiments, and the description of the above embodiments is merely intended to aid in the understanding of the method of the present disclosure and its core idea. At the same time, changes may be made by those skilled in the art to both the specific implementations and the scope of present disclosure in accordance with the teachings of the present disclosure. In view of the foregoing, the content of the present specification should not be construed as limiting the disclosure.

What is claimed is:

1. A film, wherein a material of the film comprises n-type semiconductor material and modifier, and the modifier comprises benzothiadiazole compound.

2. The film according to claim 1, wherein the modifier comprises a first modifier, and the first modifier comprises the benzothiadiazole compound, and the film comprises a first sub-film, and a material of the first sub-film comprises the n-type semiconductor material and the first modifier; or
the modifier comprises a second modifier, and the second modifier comprises the benzothiadiazole compound, and the film comprises a first sub-film and a second sub-film which are arranged in layers, wherein a material of the first sub-film comprises the n-type semiconductor material, and a material of the second sub-film comprises the second modifier; or
the modifier comprises a first modifier and a second modifier, the first modifier and the second modifier are independently selected from the benzothiadiazole compound, and the film comprises a first sub-film and a second sub-film which are arranged in layers, wherein a material of the first sub-film comprises the n-type semiconductor material and the first modifier, and a material of the second sub-film comprises the second modifier.

3. The film according to claim 2, wherein the material of the first sub-film comprises the n-type semiconductor material and the first modifier, a mass ratio of the n-type semiconductor material to the first modifier is 30:(1-5).

4. The film according to claim 2, wherein a thickness of the first sub-film ranges between 10 nm-50 nm;
a thickness of the second sub-film ranges between 1 nm-5 nm; and
a material of the first modifier and the second modifier are the same or different.

5. The film according to claim 1, wherein a structural formula of the benzothiadiazole compound is shown in the following formula: 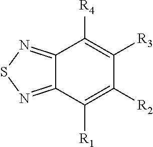
wherein R₁, R₂, R₃ and R₄ are independently selected from hydrogen, deuterium, halogen, cyano, hydroxyl, carboxyl, aldehyde, nitro, substituted or unsubstituted C₁-C₂₀ alkyl group, substituted or unsubstituted C₂-C₂₀ alkenyl group, substituted or unsubstituted C₂-C₂₀ alkynyl group, substituted or unsubstituted C₁-C₂₀ alkoxy group and substituted or unsubstituted C₁-C₂₀ alkoxy group.

6. The film according to claim 5, wherein the halogen is selected from one or more of fluorine, chlorine, bromine and iodine;
the alkyl group is selected from one or more of methyl, ethyl, isopropyl and tert-butyl;
the alkenyl group is selected from one or more of vinyl group, propylene group and butene group;
the alkynyl group is selected from one or more of ethynyl group, propynyl group, pentynyl group and heptylynyl group;
the alkoxy group is selected from one or more of methoxy, ethoxy and propoxy;
the acyloxy is selected from one or more of formyloxy, acetoxy, propionyloxy, butyryloxy, octanoyloxy, palmitoyloxy and stearoyloxy;
the alkoxycarbonyl group is selected from one or more of methoxycarbonyl group, ethoxycarbonyl group, propoxycarbonyl group, butoxycarbonyl group, octyloxycarbonyl group, palmyloxycarbonyl group and stearyloxycarbonyl group;
the heteroatom in the heterocyclic group is selected from one or more of O, P, N and S;
the heterocyclic group is selected from one or more of thiazolyl, thienyl, furyl, pyrrolyl, pyridyl, pyrimidinyl, imidazolyl, oxazolyl, pyrazinyl, indolyl, quinoline, pteridinyl and acridine;
the aryl group is selected from one or more of phenyl, p-tolyl, p-nitrophenyl, o-methoxyphenyl, m-methoxyphenyl, p-methoxyphenyl and p-nitromethoxyphenyl; and
the substituted group is independently selected from one or more of —NH, —F, —Cl, —Br, —I, —OH, —COOH, —NO, —SOH, —CHO, —SH and —CN.

7. The film according to claim 1, wherein the benzothiadiazole compound is selected from 2,1,3-benzothiadiazole, 2,1,3-benzothiadiazol-4-yl isoxyanate, 4-aminobenzo-2,1,3-thiadiazole, 2,1,3-benzothiadiazole-5-carbaldehyde, 2-mercapto-5-methyl-1,3,4-thiadiazole, 4-nitro-2,1,3-benzothiadiazole, 1,2,3-benzothiadiazole-5-carbonyl chloride, 4,7-dibromo-2,1,3-benzothiadiazole, 5-methyl-2-mercaptobenzothiazole and cyclohexylamine salt of 2-mercaptobenzothioazole.

8. The film according to claim 1, wherein an average particle size of the n-type semiconductor material ranges between 2 nm-6 nm; and
the n-type semiconductor material is selected from one or more of first doped metal oxide particle, first undoped metal oxide particle, IIB-VIA semiconductor material, IIIA-VA semiconductor material and IB-IIIA-VIA semiconductor material, and a material of the first undoped metal oxide particle is selected from one or more of ZnO, TiO₂, SnO₂, ZrO₂ and Ta₂O₅, and a metal oxide in the first doped metal oxide particle is selected from one or more of ZnO, TiO₂, SnO₂, ZrO₂, Ta₂O₅ and Al₂O₃, and a doping element in the first doped metal oxide particle is selected from one or more of Al, Mg, Li, Mn, Y, La, Cu, Ni, Zr, Ce, In and Ga, and the IIB-VIA semiconductor material is selected from one or more of ZnS, ZnSe and CdS, and the IIIA-VA semiconductor material is selected from one or more of InP and GaP, and the IB-IIIA-VIA family semiconductor material is selected from one or more of CuInS and CuGaS.

9. A preparation method of a film, comprising:
forming a film, wherein a material of the film comprises n-type semiconductor material and modifier, and the modifier comprises benzothiadiazole compound.

10. The preparation method according to claim 9, wherein the modifier comprises a first modifier, and the first modifier comprises the benzothiadiazole compound, and the film comprises a first sub-film, the formation of the film comprising:
forming a first sub-film, wherein a material of the first sub-film comprises the n-type semiconductor material and the first modifier.

11. The preparation method according to claim 10, wherein a method of forming the first sub-film comprising: proving a first mixed liquid, wherein the first mixed liquid comprises the n-type semiconductor material and the first modifier; and deposing the first mixed liquid to form the first sub-film; wherein
a mass concentration of the n-type semiconductor material in the first mixed liquid ranges between 10 mg/ml-50 mg/ml;
a mass concentration of the first modifier in the first mixed solution ranges between 1 mg/ml-5 mg/ml;
the first mixed liquid further comprises a first solvent, and the first solvent is selected from one or more of chlorobenzene, diethylene glycol monobutyl ether, trimethoxybutanol, triethylene glycol monobutyl ether, diethylene glycol dimethyl ether, methanol, ethanol, propanol, butanol, ethylene glycol, isopropanol, glycerol, dimethyl sulfoxide, acetone, acetophenone, tetrahydrofuran, N,N-dimethylformamide, ethyl acetate, pyrrole, butyric acid and cresol; and
after deposing the first mixed liquid, the method of forming the first sub-film further comprising: annealing; and s temperature of the annealing ranges between 80° C.-120° C., and a time of the annealing ranges between 5 min-10 min.

12. The preparation method according to claim 9, wherein the modifier comprises a second modifier, and the second modifier comprises the benzothiadiazole compound, and the film comprises a first sub-film and a second sub-film, the formation of the film comprising:
forming a first sub-film, wherein a material of the first sub-film comprises the n-type semiconductor material; and forming a second sub-film on the first sub-film, wherein a material of the second sub-film comprises the second modifier; or
forming a second sub-film, wherein a material of the second sub-film comprises the second modifier; and forming a first sub-film on the second sub-film, wherein a material of the first sub-film comprises the n-type semiconductor material.

13. The preparation method according to claim 12, wherein a method of forming the second sub-film comprising: proving a second mixed liquid, wherein the second mixed liquid comprises the second modifier; and deposing the second mixed liquid to form the second sub-film; wherein
a mass concentration of the second modifier in the second mixed solution ranges between 1 mg/ml-5 mg/ml; and
the second mixed liquid further comprises a second solvent, and the second solvent is selected from one or more of chlorobenzene, diethylene glycol monobutyl ether, trimethoxybutanol, triethylene glycol monobutyl ether, diethylene glycol dimethyl ether, methanol, ethanol, propanol, butanol, ethylene glycol, isopropanol, glycerol, dimethyl sulfoxide, acetone, acetophenone, tetrahydrofuran, N,N-dimethylformamide, ethyl acetate, pyrrole, butyric acid and cresol.

14. The preparation method according to claim 9, wherein the modifier comprises a first modifier and a second modifier, and the first modifier and the second modifier are independently selected from the benzothiadiazole compound, and the film comprises a first sub-film and a second sub-film, the formation of the film comprising:
forming a first sub-film, wherein a material of the first sub-film comprises the n-type semiconductor material and the first modifier; and forming a second sub-film on the first sub-film, wherein a material of the second sub-film comprises the second modifier; or
forming a second sub-film, wherein a material of the second sub-film comprises the second modifier; and forming a first sub-film on the second sub-film, wherein a material of the first sub-film comprises the n-type semiconductor material and the first modifier.

15. The preparation method according to claim 9, wherein the benzothiadiazole compound is selected from 2,1,3-benzothiadiazole, 2,1,3-benzothiadiazol-4-yl isoxyanate, 4-aminobenzo-2,1,3-thiadiazole, 2,1,3-benzothiadiazole-5-carbaldehyde, 2-mercapto-5-methyl-1,3,4-thiadiazole, 4-nitro-2,1,3-benzothiadiazole, 1,2,3-benzothiadiazole-5-carbonyl chloride, 4,7-dibromo-2,1,3-benzothiadiazole, 5-methyl-2-mercaptobenzothiazole and cyclohexylamine salt of 2-mercaptobenzothioazole; and
the n-type semiconductor material is selected from one or more of first doped metal oxide particle, first undoped metal oxide particle, IIB-VIA semiconductor material, IIIA-VA semiconductor material and IB-IIIA-VIA semiconductor material, and a material of the first undoped metal oxide particle is selected from one or more of ZnO, TiO₂, SnO₂, ZrO₂ and Ta₂O₅, and a metal oxide in the first doped metal oxide particle is selected from one or more of ZnO, TiO₂, SnO₂, ZrO₂, Ta₂O₅ and Al₂O₃, and a doping element in the first doped metal oxide particle is selected from one or more of Al, Mg, Li, Mn, Y, La, Cu, Ni, Zr, Ce, In and Ga, and the IIB-VIA semiconductor material is selected from one or more of ZnS, ZnSe and CdS, and the IIIA-VA semiconductor material is selected from one or more of InP and GaP, and the IB-IIIA-VIA family semiconductor material is selected from one or more of CuInS and CuGaS.

16. A photoelectric device, comprising:
an anode;
a cathode;
several photoelectric units, located between the anode and the cathode; and
a connecting layer, located between every two adjacent photoelectric units, and each connecting layer comprises an electron generating layer and a hole generating layer arranged in sequence along the direction away from the anode;
wherein the electron generating layer comprises a film, and a material of the film comprises n-type semiconductor material and modifier, and the modifier comprises benzothiadiazole compound.

17. The photoelectric device according to claim 16, wherein the modifier comprises a first modifier, and the first modifier comprises the benzothiadiazole compound, and the film comprises a first sub-film, and a material of the first sub-film comprises the n-type semiconductor material and the first modifier; or
the modifier comprises a second modifier, and the second modifier comprises the benzothiadiazole compound, and the film comprises a first sub-film and a second sub-film which are arranged in layers, and the second sub-film is located between the first sub-film and the hole generating layer, wherein a material of the first sub-film comprises the n-type semiconductor material, and a material of the second sub-film comprises the second modifier; or
the modifier comprises a first modifier and a second modifier, the first modifier and the second modifier are independently selected from the benzothiadiazole compound, and the film comprises a first sub-film and a second sub-film which are arranged in layers, and the second sub-film is located between the first sub-film and the hole generating layer, wherein a material of the first sub-film comprises the n-type semiconductor material and the first modifier, and a material of the second sub-film comprises the second modifier.

18. The photoelectric device according to claim 17, wherein the photoelectric units comprise a first photoelectric unit and a second photoelectric unit, and the first photoelectric unit comprises a first hole functional layer, a first luminescent layer, and a first electronic functional layer which are sequentially stacked, the second photoelectric unit comprises a second hole functional layer, a second luminescent layer, and a second electronic functional layer which are sequentially stacked.

19. The photoelectric device according to claim 18, wherein the photoelectric device is an upright photoelectric device, comprising: the anode, the first hole functional layer, the first luminescent layer, the first electronic functional layer, the first sub-film, the second sub-film, the hole generating layer, the second hole functional layer, the second luminescent layer, the second electronic functional layer and the cathode which are sequentially stacked; or
the photoelectric device is an inverted photoelectric device, comprising: the cathode, the second electronic functional layer, the second luminescent layer, the second hole functional layer, the hole generating layer, the second sub-film, the first sub-film, the first electronic functional layer, the first luminescent layer, the first hole functional layer and the anode which are sequentially stacked;
wherein a material of the first sub-film comprises the n-type semiconductor, or a material of the first sub-film comprises the n-type semiconductor material and the first modifier.

20. The photoelectric device according to claim 18, wherein a material of the anode and the cathode is each independently selected from one or more of metal, carbon material and metal oxide, and the metal is selected from one or more of Al, Ag, Cu, Mo, Au, Ba, Ca, Yb and Mg, and the carbon material is selected from one or more of graphite, carbon nanotubes, graphene and carbon fiber, and the metal oxide is selected from one or more of metal oxide electrode or composite electrode with metal sandwiched between doped or undoped transparent metal oxide, and a material of the metal oxide electrode is selected from one or more of ITO, FTO, ATO, AZO, GZO, IZO, MZO, MoO₃ and AMO, and the composite electrode is selected from one or more of AZO/Ag/AZO, AZO/Al/AZO, ITO/Ag/ITO, ITO/Al/ITO, ZnO/Ag/ZnO, ZnO/Al/ZnO, ZnS/Ag/ZnS, ZnS/Al/ZnS, TiO₂/Ag/TiO₂ and TiO₂/Al/TiO₂;
a material of luminescent layer in each photoelectric unit is independently selected from one or more of organic luminescent material and quantum dot luminescent material; and a material of the organic luminescent material is selected from one or more of CBP:Ir(mppy)3, TCTX:Ir(mmpy), diarylanthracene derivatives, stilbene aromatic derivatives, pyrene derivatives, fluorene derivatives, TBPe fluorescent materials, TTPX fluorescent materials, TBRb fluorescent materials, DBP fluorescent materials, delayed fluorescent materials, TTA materials, TADF materials, polymers containing B—N covalent bonds, HLCT materials and Exciplex luminescent materials, and the quantum dot luminescent material is selected from one or more of single-structure quantum dot, core-shell quantum dot and perovskite-type semiconductor material; a material of the single-structure quantum dot, a core material of the core-shell quantum dot and a shell material of the core-shell quantum dot might be respectively selected from but not limited to one or more of second II-VI compound, second IV-VI compound, second III-V compound and I-III-VI compound; and a shell layer of the core-shell structure quantum dot comprises one or more layers; the second II-VI compound is selected from one or more of CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe; the second IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe and SnPbSTe; the second III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs and InAlPSb; the I-III-VI compound is selected from one or more of CuInS₂, CuInSe₂ and AgInS₂; and the core-shell quantum dot is selected from one or more of CdSe/CdSeS/CdS, InP/ZnSeS/ZnS, CdZnSe/ZnSe/ZnS, CdSe/ZnS, CdSe/ZnSe, ZnSe/ZnS, ZnSe/ZnS, ZnSe/ZnS, and ZnSe/ZnSe/ZnSe; and the perovskite semiconductor material is selected from one of doped or undoped inorganic perovskite semiconductor or organic-inorganic hybrid perovskite semiconductor; a general structural formula of the inorganic perovskite semiconductor is AMX₃, wherein A is Cs⁺, and X is divalent metal cation, which is selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺ and Eu²⁺, and X is a halogen anion selected from one or more of Cl⁻, Br⁻ and I⁻; the general structural formula of the organic-inorganic hybrid perovskite semiconductor is BMX₃, wherein B is an organic amine cation selected from CH₃(CH₂)ₙ₋₂NH₃⁺ or [NH₃(CH₂)ₙNH₃]²⁺, wherein n≥2, and M is a divalent metal cation selected from Pb²⁺, Sn²⁺, Cu²⁺, Ni²⁺, Cd²⁺ and Cr³⁺, and X is a halogen anion selected from one or more of Cl⁻, Br⁻ and I⁻;
a material of the hole functional layer and the hole generating layer is each independently selected from one or more of 4,4′-N,N′-dicarbazolyl-biphenyl, N,N′-diphenyl-N,N′-bis (1-naphthyl)-1,1′-biphenyl)-4,4′-diamine, N,N′-bis(3-methylphenyl)-N,N′-bis (phenyl)-spiro, N,N′-bis(4-(N,N′-diphenyl-amino) phenyl)-N,N′-diphenylbenzidine, 4,4′,4′-tris (N-carbazolyl)-triphenylamine, 4,4′,4′-tris (carbazole-9-yl) triphenylamine, trichloroisocyanuric acid, terbium-doped phosphate-based green luminescent material, 2,3,6,7,10,11-hexacyano-1,4,5,8,9,12-hexaazaphenanthrene, 4,4′,4′-tris (N-3-methylphenyl-N-phenylamino) triphenylamine, poly [(9,9′-dioctyl fluorene-2,7-diyl)-co-(4,4′-(N-(4-sec-butylphenyl) diphenylamine))], poly (4-butylphenyl-diphenylamine), poly [bis(4-phenyl) (4-butylphenyl) amine], polyaniline, polypyrrole, poly (p) phenylene vinylene, poly (phenylene vinylene), poly [2-methoxy-5-(2-ethylhexyloxy)-1,4-phenylene vinylene], poly [2-methoxy-5-(3′,7′-dimethyl octyloxy)-1,4-phenylene vinylene], copper phthalocyanine, aromatic tertiary amine, 4,4′-bis (p-carbazolyl)-1,1′-biphenyl compound, N,N,N′,N′-tetraarylbenzidine, PEDOT, PEDOT:PSS and its derivatives, PEDOT:PSS derivatives doped with s-MoO₃, poly (N-vinylcarbazole) and its derivatives, polymethacrylate and its derivatives, poly (9,9-octylfluorene) and its derivatives, poly (spirofluorene) and its derivatives, N,N′-bis(naphthalene-1-yl)-N,N′-diphenylbenzidine, spiro NPB, nano-polycrystalline diamond, microcrystalline cellulose, tetracyanoquinone dimethylmethane, doped graphene and undoped graphene, second doped metal oxide particle, second undoped metal oxide particle, metal sulfide, metal selenide and metal nitride, and a metal oxide in the second doped metal oxide particle and a metal oxide in the second undoped metal oxide particle is independently selected from one or more of MoO₃, WO₃, NiO, CrO₃, CuO, Cu₂O and V₂O₅, and a doping element in the second doped metal oxide particle is selected from one or more of Mo, W, Ni, Cr, Cu and V, and the metal sulfide is selected from one or more of CuS, MoS₃ and WS₃, and the metal selenide is selected from one or more of MoSe₃ and WSe₃, and the metal nitride is selected from p-type gallium nitride; and
a material of the electronic functional layer is selected from one or more of first doped metal oxide particle, first undoped metal oxide particle, IIB-VIA semiconductor material, IIIA-VA semiconductor material and IB-IIIA-VIA semiconductor material, and a material of the first undoped metal oxide particle is selected from one or more of ZnO, TiO₂, SnO₂, ZrO₂ and Ta₂O₅, and a metal oxide in the first doped metal oxide particle is selected from one or more of ZnO, TiO₂, SnO₂, ZrO₂, Ta₂O₅ and Al₂O₃, and a doping element in the first doped metal oxide particle is selected from one or more of Al, Mg, Li, Mn, Y, La, Cu, Ni, Zr, Ce, In and Ga, and the IIB-VIA semiconductor material is selected from one or more of ZnS, ZnSe and CdS, and the IIIA-VA semiconductor material is selected from one or more of InP and GaP, and the IB-IIIA-VIA family semiconductor material is selected from one or more of CuInS and CuGaS.
